(19) United States
(12) Patent Application Publication
(10) Pub. No.: US 2018/0074144 A1
(43) Pub. Date: Mar. 15, 2018

(54) COMBINING SIMULTANEOUS MAGNETIC RESONANCE IMAGING (MRI) AND POSITRON-EMISSION TOMOGRAPHY (PET)

(71) Applicant: Aspect Imaging Ltd., Shoham (IL)

(72) Inventors: Aviad Dezorayev, Shoham (IL); Yaki Stern, Shoham (IL); Zahi Inbar, Shoham (IL); Tobi Reuveni, Shoham (IL); Shaul Bilu, Shoham (IL); Ron Nave, Shoham (IL); Oren Bash, Shoham (IL)

(73) Assignee: Aspect Imaging Ltd.

(21) Appl. No.: 15/700,839

(22) Filed: Sep. 11, 2017

Related U.S. Application Data
(60) Provisional application No. 62/393,059, filed on Sep. 11, 2016.

(51) Int. Cl. G01R 33/48; G01R 33/422; G01R 33/34; G01T 1/29

(52) U.S. Cl. CPC G01R 33/481; G01T 1/2985; G01R 33/34046; G01R 33/422

(57) ABSTRACT

Systems and methods for simultaneous acquisition of MRI data and PET data of a subject are disclosed. The system can include a RF coil surrounding the subject and a PET detectors array surrounding the RF coil to generate the MRI data and the PET data of the subject, respectively. The system can include a RF shield positioned between the RF coil and the PET detectors array to prevent an interference between the RF coil and the PET detectors array to thereby allow simultaneous acquisition of the MRI data and the PET data without any one of the RF coil, the PET detectors array or the subject being moved during the imaging. The system can include an analysis unit to generate, based on the simultaneously acquired MRI data and PET data, combined PET-MRI images of the subject that include a spatially and temporally registered structural, functional and/or molecular data acquired under identical physiological conditions.

### CROSS REFERENCE TO RELATED APPLICATIONS

This application claims the benefit of and priority to U.S. Provisional Application No. 62/393,059 filed on Sep. 11, 2016, which is incorporated herein by reference in its entirety.

### FIELD OF THE INVENTION

The present invention relates to the field of combined Positron Emission Tomography (PET) and Magnetic Resonance Imaging (MRI) systems.

### BACKGROUND OF THE INVENTION

Current combined Positron Emission Tomography (PET) and Magnetic Resonance Imaging (MRI) systems typically require moving at least one of MRI device's RF coil, PET detectors and/or a subject during an imaging procedure. For example, some systems house both a PET imaging device and a MRI imaging device. These systems can require that a subject be positioned relative to the PET detectors for a PET image to be taken. Subsequently, the same subject can be moved to be positioned within an MRI imaging device for an MRI image to be taken (or vice versa, the MRI image can be taken first then the PET). In these systems, fusing the PET image and the MRI image can result in erroneous results due to, for example, the subject's position during PET imaging being different than the subject's position during MRI imaging.

Another difficulty with current systems is that a state of the subject may be different during the PET image and the MRI image due to, for example, a delay between taking the PET image and the MRI image. The delay between taking the two images can also cause erroneous results. Therefore, it can be desirable to provide simultaneous PET and MRI imaging of the subject.

### SUMMARY OF THE INVENTION

One aspect of the present invention provides a system for combined magnetic resonance imaging (MRI) and Positron-Emission Tomography (PET). The system can include: at least one magnet to generate a magnetic field within a predetermined measurement volume; a radiofrequency (RF) coil having a RF coil bore that at least partly overlaps the predetermined measurement volume and having a diameter to accommodate at least a portion of a subject, the RF coil to generate an electromagnetic field within the RF coil bore to excite nuclei within the at least portion of the subject and to receive signals emitted from the at least portion of the subject when the electromagnetic field is removed and the excited nuclei relax; a PET detectors array surrounding the RF coil and to detect gamma rays emitted by positron-emitting (PE) radionuclides within the subject; and a RF shield surrounding the RF coil and positioned between the RF coil and the PET detectors array.

In some embodiments, the system further includes an analysis unit in communication with at least one of the RF coil and the PET detectors array. The analysis unit can: generate, based on MRI data acquired by the RF coil, at least one MRI image of the at least portion of the subject; generate, based on PET data acquired by the PET detectors array, at least one PET image of the at least portion of the subject; and combine at least one of the MRI images with at least one of the PET images to thereby generate at least one combined PET-MRI image.

In some embodiments, the MRI device includes at least one of permanent magnets, superconductive magnets or a combination thereof to generate a magnetic field within the predetermined measurement volume.

In some embodiments, the RF coil and the detector array are positioned such that the subject, RF coil and the detector array are stationary during operation.

In some embodiments, the RF shield comprises at least one of a cylinder or a mesh made from a conductive material.

In some embodiments, the RF shield to form a Faraday cage to thereby provide RF shielding of the system.

In some embodiments, the RF coil and the PET detectors array are positioned concentrically or at a predetermined radial distance with respect to each other.

In some embodiments, the at least one MRI image and the at least one PET image includes at least one of a set of temporary sequential images, a set of spatial images or any combination thereof.

In some embodiments, the system is configured to perform the combining by at least one of registering, superimposing, fusing or any combination thereof of at least one of the MRI images and at least one of the PET images.

Another aspect of the present invention provides a method of generating at least one combined magnetic resonance imaging (MRI) image and Positron-Emission Tomography (PET) image. The method can include: preventing a radiofrequency (RF) radiation generated by a RF coil from interfering with operation of a PET detectors array and a RF radiation generated by the PET detectors array from interfering with operation the RF coil; generating, based on MRI data acquired by the RF coil, at least one MRI image of at least a portion of a subject; generating, based on PET data acquired by the PET detectors array, at least one PET image of the at least portion of the subject; and combining at least one of the MRI images with at least one of the PET images to thereby generate at least one combined PET-MRI image.

In some embodiments, the method further includes operating the RF coil and the detector array simultaneously or separately without any one of the RF coil, the PET detectors array or the subject being moved during an imaging procedure.

In some embodiments, the combining includes at least one of registering, superimposing, fusing or any combination thereof of at least one of the MRI images and at least one of the PET images.

Another aspect of the present invention provides a device for combined magnetic resonance imaging (MRI) and Positron-Emission Tomography (PET), which is operative in a MRI device. The device can include: a radiofrequency (RF) coil having a RF coil bore that at least partly overlaps a predetermined measurement volume of the MRI device and having a diameter to accommodate at least a portion of a subject, the RF coil to generate an electromagnetic field within the RF coil bore to excite nuclei within the at least portion of the subject and to receive signals emitted from the at least portion of the subject when the electromagnetic field is removed and the excited nuclei relax; a PET detectors array surrounding the RF coil and to detect gamma rays emitted by positron-emitting (PE) radionuclides within the subject; and a RF shield surrounding the RF coil and positioned between the RF coil and the PET detectors array.

In some embodiments, the device includes an analysis unit in communication with at least one of the RF coil, the PET detectors array and the MRI device. The analysis unit can: generate, based on MRI data acquired by the RF coil, at least one MRI image of the at least portion of the subject; generate, based on PET data acquired by the PET detectors array, at least one PET image of the at least portion of the subject; and combine at least one of the MRI images with at least one of the PET images to thereby generate at least one combined PET-MRI image.

In some embodiments, the MRI device includes at least one of permanent magnets, superconductive magnets or a combination thereof to generate a magnetic field within the predetermined measurement volume of the MRI device.

In some embodiments, the RF coil and the detector array are positioned such that the subject, RF coil and the detector array are stationary during operation.

In some embodiments, the RF shield includes at least one of a cylinder or a mesh made from a conductive material.

In some embodiments, the RF shield to form a Faraday cage to thereby provide RF shielding of the system.

In some embodiments, each of the at least one MRI image and the at least one PET image comprises at least one of a set of temporary sequential images, a set of spatial images or any combination thereof.

In some embodiments, the device is configured to perform the combining by at least one of registering, superimposing, fusing or any combination thereof of at least one of the MRI images and at least one of the PET images.

These, additional, and/or other aspects and/or advantages of the present invention are set forth in the detailed description which follows; possibly inferable from the detailed description; and/or learnable by practice of the present invention.

### BRIEF DESCRIPTION OF THE DRAWINGS

Non-limiting examples of embodiments of the disclosure are described below with reference to figures attached hereto that are listed following this paragraph. Dimensions of features shown in the figures are chosen for convenience and clarity of presentation and are not necessarily shown to scale.

The subject matter regarded as the invention is particularly pointed out and distinctly claimed in the concluding portion of the specification. The invention, however, both as to organization and method of operation, together with objects, features and advantages thereof, can be understood by reference to the following detailed description when read with the accompanied drawings. Embodiments of the invention are illustrated by way of example and not limitation in the figures of the accompanying drawings, in which like reference numerals indicate corresponding, analogous or similar elements, and in which:

FIG. 1 is a block diagram of a system for combined Positron-Emission Tomography (PET) and Magnetic Resonance Imaging (MRI), according to some embodiments of the invention;

FIG. 2A is a schematic illustration of a system for combined Positron-Emission Tomography (PET) and Magnetic Resonance Imaging (MRI), according to some embodiments of the invention;

FIG. 2B shows schematic illustrations of a RF coil structure of a system for combined Positron-Emission Tomography (PET) and Magnetic Resonance Imaging (MRI), according to some embodiments of the invention;

FIG. 2C shows schematic illustrations of a PET structure of a system for combined Positron-Emission Tomography (PET) and Magnetic Resonance Imaging (MRI), according to some embodiments of the invention;

FIG. 2D shows schematic illustrations of a radiofrequency (RF) shield of a system for combined Positron-Emission Tomography (PET) and Magnetic Resonance Imaging (MRI) including two RF shield parts, according to some embodiments of the invention;

FIG. 2E is a schematic illustrations of a radiofrequency (RF) sleeve of a system for combined Positron-Emission Tomography (PET) and Magnetic Resonance Imaging (MRI), according to some embodiments of the invention;

FIG. 2F and FIG. 2G are schematic illustrations of a RF shield, RF coil structure and PET structure in a disassembled state external to a housing and in an assembled state within the housing of a system for combined Positron-Emission Tomography (PET) and Magnetic Resonance Imaging (MRI), respectively, according to some embodiments of the invention;

FIG. 3 is an example of a simultaneously acquired MRI image and PET image, and a combined PET-MRI image of a subject generated by a system for combined Positron-Emission Tomography (PET) and Magnetic Resonance Imaging (MRI), according to some embodiments of the invention; and

FIG. 4 is a flowchart of a method of generating at least one combined magnetic resonance imaging (MRI) image and Positron-Emission Tomography (PET) image, according to some embodiments of the invention.

### DETAILED DESCRIPTION OF THE INVENTION

In the following description, various aspects of the present invention are described. For purposes of explanation, specific configurations and details are set forth in order to provide a thorough understanding of the present invention. However, it will also be apparent to one skilled in the art that the present invention can be practiced without the specific details presented herein. Furthermore, well known features can have been omitted or simplified in order not to obscure the present invention. With specific reference to the drawings, it is stressed that the particulars shown are by way of example and for purposes of illustrative discussion of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention can be embodied in practice.

Before at least one embodiment of the invention is explained in detail, it is to be understood that the invention is not limited in its application to the details of construction and the arrangement of the components set forth in the following description or illustrated in the drawings. The invention is applicable to other embodiments that can be practiced or carried out in various ways as well as to combinations of the disclosed embodiments. Also, it is to be understood that the phraseology and terminology employed herein is for the purpose of description and should not be regarded as limiting.

Systems and methods for simultaneous acquisition of MRI data and PET data of a subject are disclosed. The system can include a RF coil surrounding the subject and a PET detectors array surrounding the RF coil to generate the MRI data and the PET data of the subject, respectively. The system can include a RF shield positioned between the RF coil and the PET detectors array to prevent (or substantially prevent) an interference between the RF coil and the PET detectors array to thereby allow simultaneous acquisition of the MRI data and the PET data without any one of the RF coil, the PET detectors array or the subject being moved during the imaging. The system can include an analysis unit to generate, based on the simultaneously acquired MRI data and PET data, combined PET-MRI images of the subject that include a spatially and temporally registered structural, functional and/or molecular data acquired under identical physiological conditions.

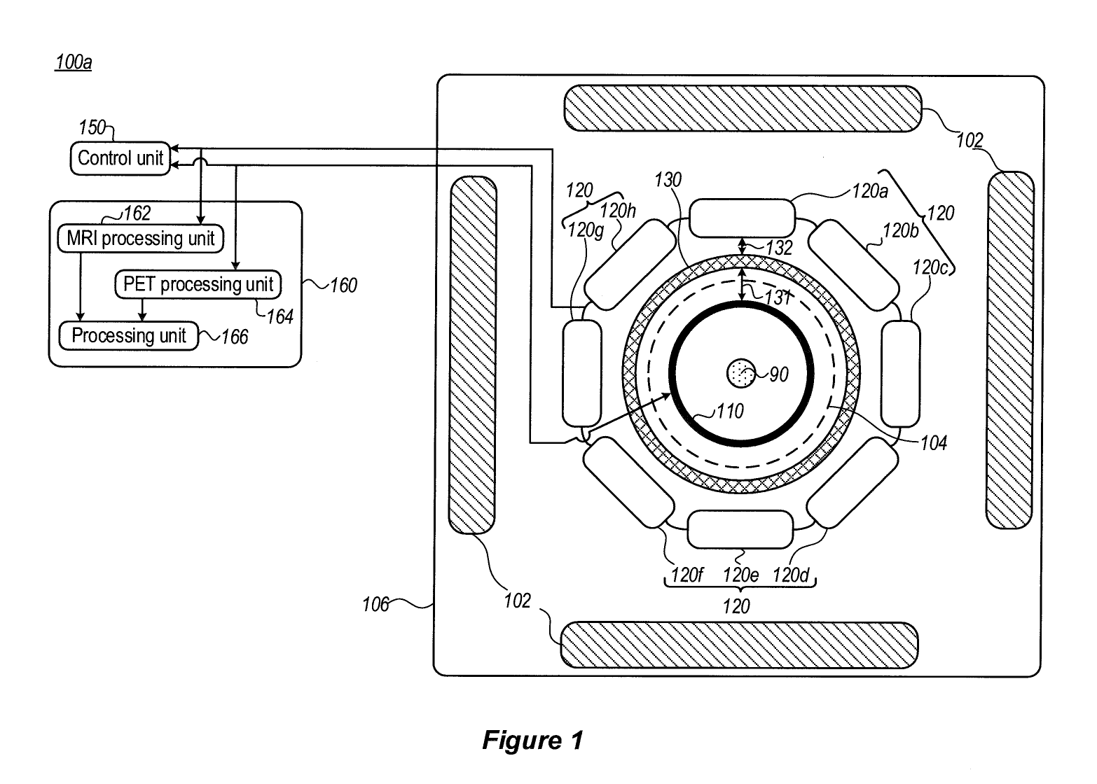

Reference is now made to FIG. 1, which is a block diagram of a system 100 for combined Positron-Emission Tomography (PET) and Magnetic Resonance Imaging (MRI), according to some embodiments of the invention.

System 100 can include at least one magnet 102 to generate a magnetic field within a predetermined measurement volume 104. In various embodiments, magnets 102 include at least one of permanent magnets, superconductive magnets or a combination thereof.

System 100 can include a housing 106b to at least partly surround magnets 102. Housing 106b can, for example, substantially eliminate a magnetic fringe field generated by magnets 102 outside housing 106.

System 100 can include a radiofrequency (RF) coil 110 (e.g., solenoid) having a RF coil bore 111, a RF coil diameter and a RF coil length. The RF coil diameter and/or the RF coil length can have values that allow RF coil 110 to accommodate a subject 90 (e.g., a mouse), or at least a portion of subject 90, within RF coil bore 111. RF coil bore 111 can at least partly overlap with predetermined measurement volume 104. In various embodiments, the RF coil diameter ranges between, for example 30-40 mm and/or the RF coil length ranges between, for example 40-55 mm.

RF coil 110 can generate an electromagnetic field within RF coil bore 111 to excite a magnetic moment of nuclei within subject 90 (or within a predetermined portion of subject 90). RF coil 110 can be arranged to receive signals generated due to relaxation of the excited nuclei thereof. In some embodiments, system 100 includes two (or more) RF coils, for example a first RF coil and a second RF coil (not shown), wherein first RF coil generates the electromagnetic field to excite nuclei within subject 90 and second RF coil receives the signals generated due to relaxation of the nuclei thereof.

System 100 can include a Positron-Emission Tomography (PET) detectors array 120 having a PET detectors array diameter and a PET detectors array length. PET detectors array 120 can surround RF coil 110. PET detectors array 120 can include a plurality of detectors (e.g., detectors 120a, 120b, 120c, 120d, 120e, 120f, 120g, 120h, as shown in FIG. 1) to detect gamma rays emitted by positron-emitting radionuclides within subject 90 (or within a predetermined portion of subject 90). For example, as is known in the PET art, positron-emitting radionuclides are injected into a subject (or the subject can swallow or inhale the radionuclides thereof) prior to taking PET images.

In various embodiments, RF coil 110 and PET detectors array 120 have a substantially annular shape and/or can be positioned concentrically (e.g., as shown in FIG. 1). In some embodiments, RF coil 110 and PET detectors array 120 are positioned at a predetermined radial distance with respect to each other (not shown). The position of RF coil 110 and the position of PET detectors array 120 within system 100 can be determined based on, for example, a desired application and/or desired dimensions of system 100.

System 100 can include a RF shield 130 having a RF shield diameter and a RF shield length. RF shield 130 can surround RF coil 110. RF shield 130 can be positioned between RF coil 110 and PET detectors array 120 (e.g., as shown in FIG. 1). In various embodiments, RF coil 110, PET detectors array 120 and RF shield 130 are positioned to provide a first space 131 between RF coil 110 and RF shield 130 and/or to provide a second space 132 between PET 120 and RF shield 130 (e.g., as shown in FIG. 1).

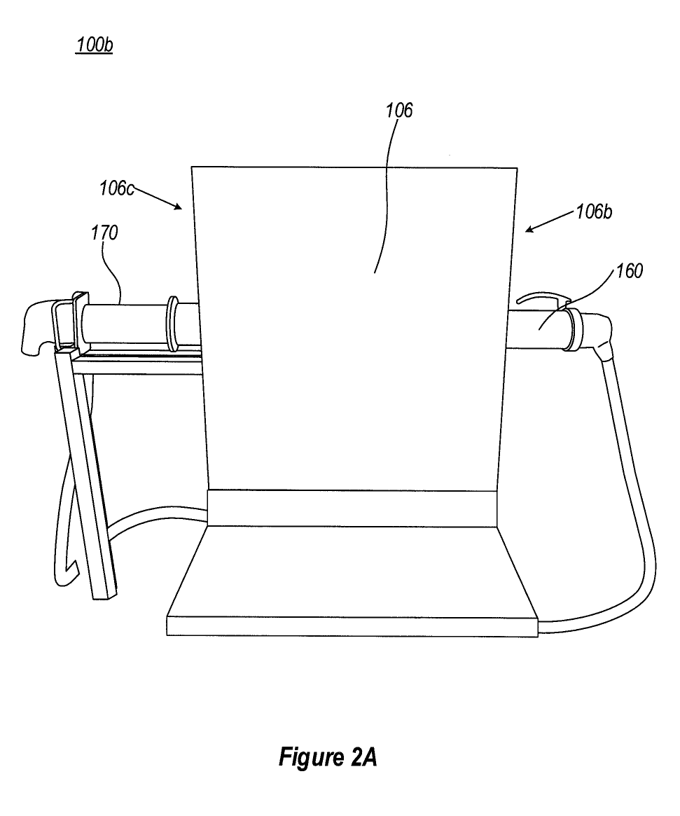

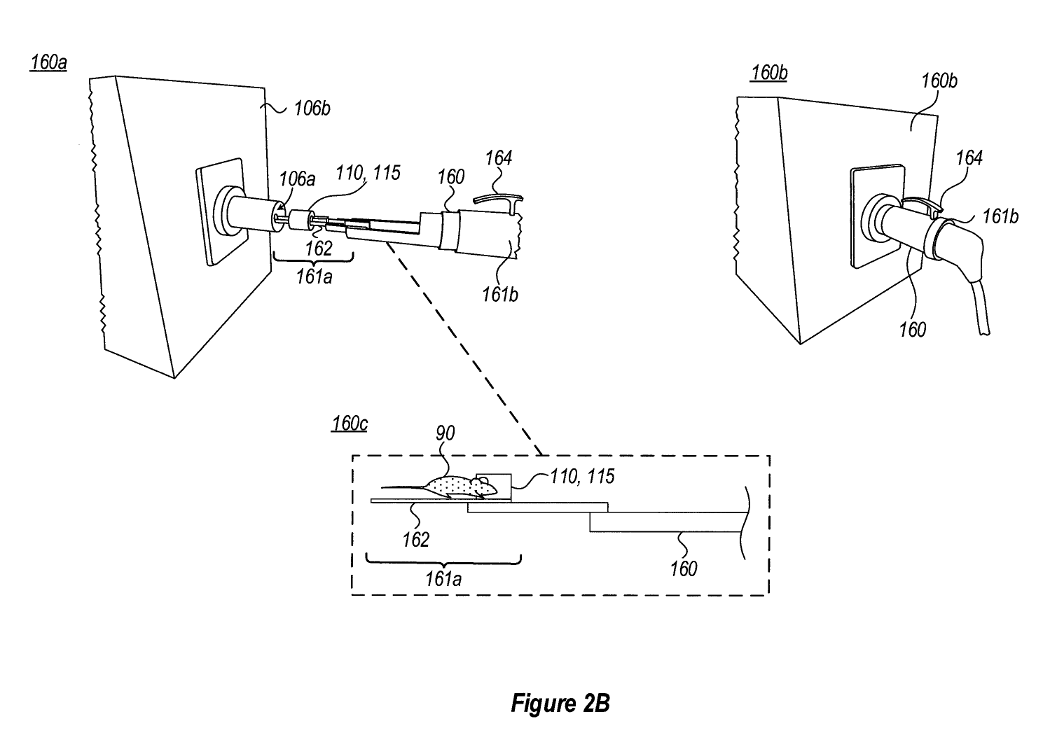

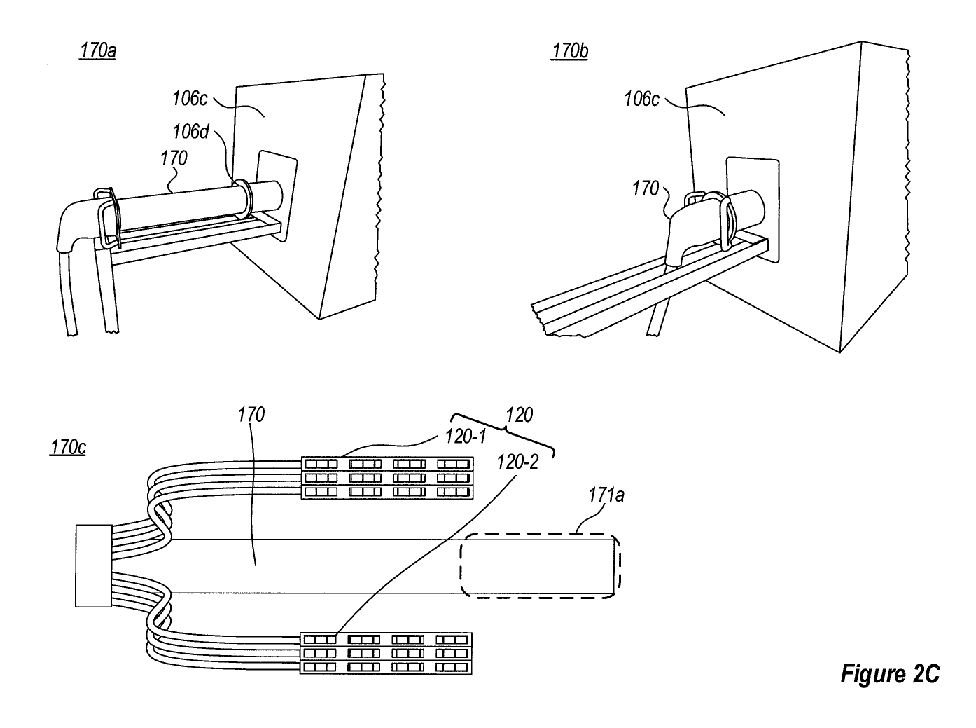

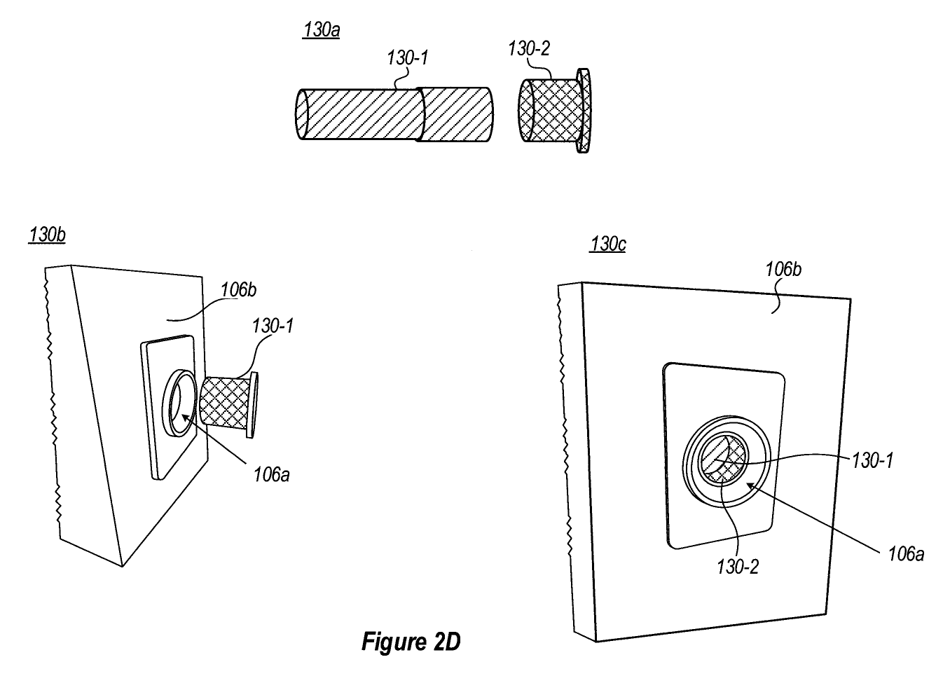

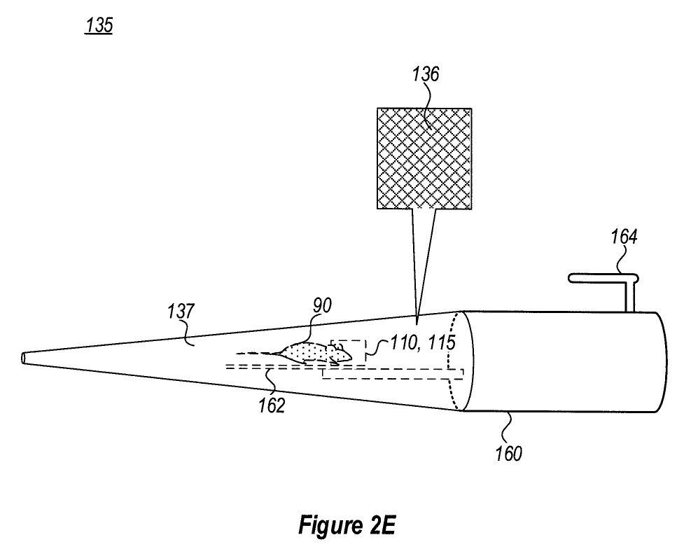

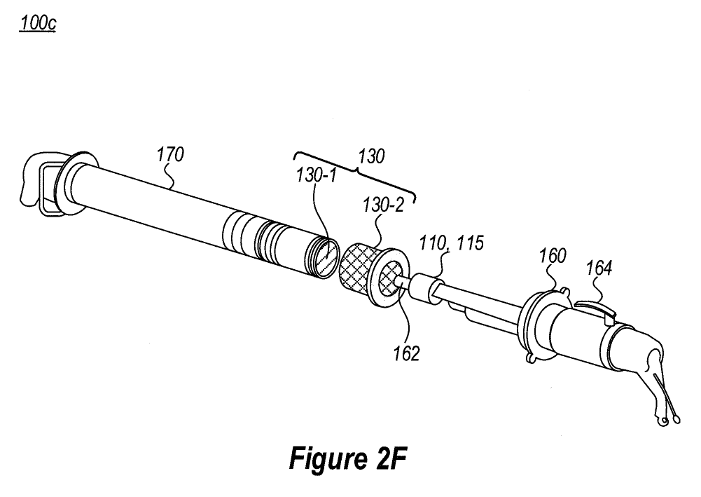

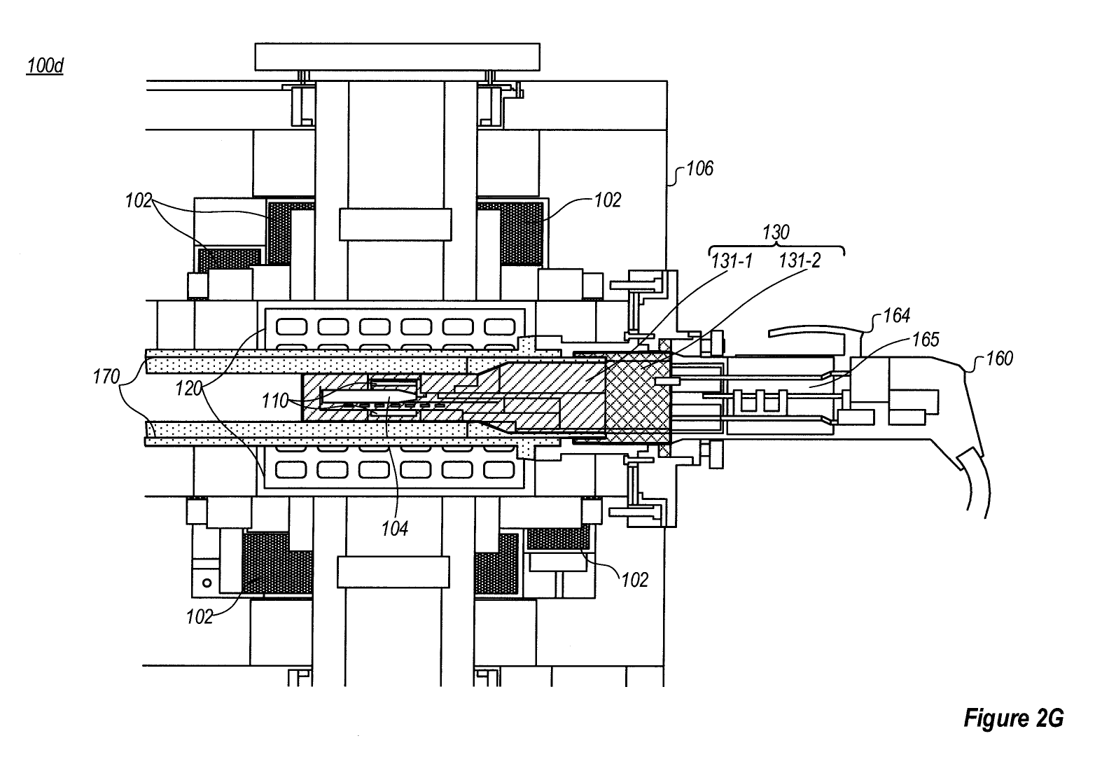

RF shield 130 can include a conductive material (e.g., copper, aluminum, and/or any other material capable of providing shielding). RF shield 130 is arranged to form a Faraday cage to provide a RF shielding (and/or electromagnetic shielding) of system 100 (e.g., as discussed below with respect to FIG. 2D and FIG. 2G). In some embodiments, the RF shielding includes, for example, preventing (or substantially preventing) a RF radiation generated by RF coil 110 from exiting RF coil bore 111 and preventing a RF radiation generated by PET detectors array 120 from entering RF coil bore 111, to thereby prevent interference between RF coil 110 and PET detectors array 120. In some embodiments, the RF shielding includes preventing (or substantially preventing) RF radiation (e.g., generated by RF coil 110) from exiting predetermined measurement volume 104 and/or preventing external RF radiation from entering predetermined measurement volume 104.

In various embodiments, first space 131 between RF coil 110 and RF shield 130 and/or second space 132 between PET detectors array 120 and RF shield 130 are determined to, for example, eliminate (or substantially eliminate) the RF shieling effect on the electromagnetic field generated by RF coil 110 within RF coil bore 111, while providing the RF shielding of PET detectors array 120 and/or of system 100 (e.g., as described above). For example, first space 131 can be larger as compared to second space 132.

System 100 can include a control unit 150 in communication with RF coil 110 and with PET detectors array 120. Control unit 150 can operate RF coil 110 and PET detectors array 120 according to a predetermined operation pattern (e.g., direct the RF coil and/or PET detector array to generate electromagnetic, magnetic fields or any combination thereof having specific intensities, directions, in accordance with operations parameters of MRI and PET as is known in the art).

In some embodiments, the predetermined operation pattern includes directing simultaneous operation of RF coil unit 110, and thus MRI imaging, and of PET detectors array 120, and thus PET imaging. For example, RF coil 110 can generate electromagnetic field within RF coil bore 111 and, at the same time, PET detectors array 120 can detect gamma rays emitted from subject 90.

As is apparent to one of ordinary skill in the art, although the system can perform simultaneous PET and MRI imaging, in some embodiments, it may be desirable to operate the system in an exclusively PET or MRI mode. In these embodiments, the predetermined operation pattern can include directions for separate operation of MRI device 80 and of PET detectors array 120. For example, RF coil 110 can generate electromagnetic field within RF coil bore 111 and, after a predetermined time delay, PET detectors array 120 can detect gamma rays emitted from subject 90, or vice versa.

In some embodiments, PET detectors array 120 is positioned such that the electromagnetic radiation produced by RF coil 110 absent RF shield 130 impinges upon PET detectors of PET detectors array 120. If the PET detectors of PET detectors array 120 are subject to the electromagnetic radiation from RF coil 110, the measurements of the PET detectors of PET detectors array 120 can be erroneous and/or completely unreadable. As described above, RF shield 130 positioned between RF coil 110 and PET detectors array 120 can prevent the electromagnetic radiation from coil 110 from ruining PET detectors array 120 measurements because, for example, PET detectors array 120 is shielded. In this manner, simultaneous PET imaging and MRI imaging can occur, without, for example, any one of RF coil 110, PET detectors array 120 and/or subject 90 being moved during an imaging procedure.

System 100 can include an analysis unit 160. Analysis unit 160 can include a MRI processing unit 162. MRI processing unit 162 can receive MRI data (e.g., signals received by RF coil 110) and generate, based on the MRI data, one or more MRI images of subject 90 (or at least a portion of subject 90). In various embodiments, the MRI images include at least one of a set of temporary sequential MRI images of subject 90, a set of spatial MRI images of subject 90 or any combination thereof.

Analysis unit 160 can include a PET processing unit 164. PET processing unit 164 can receive PET data (e.g., received by PET detectors array 120) and generate, based on the PET data, one or more PET images of subject 90 (or at least a portion of subject 90). In various embodiments, the PET images include at least one of a set of temporary sequential PET images of subject 90, a set of spatial PET images of subject 90 or any combination thereof.

Analysis unit 160 can include a processing unit 166. Processing unit 166b can receive the MRI images (e.g., from MRI processing unit 162) and the PET images (e.g., from PET processing unit 164). In various embodiments, the MRI images and/or the PET images are generated external to analysis unit 160, while analysis unit 160 can be adapted to receive the externally generated MRI images and PET images. Processing unit 166b can combine at least one of the MRI images with at least one of the PET images to thereby generate at least one combined PET-MRI image.

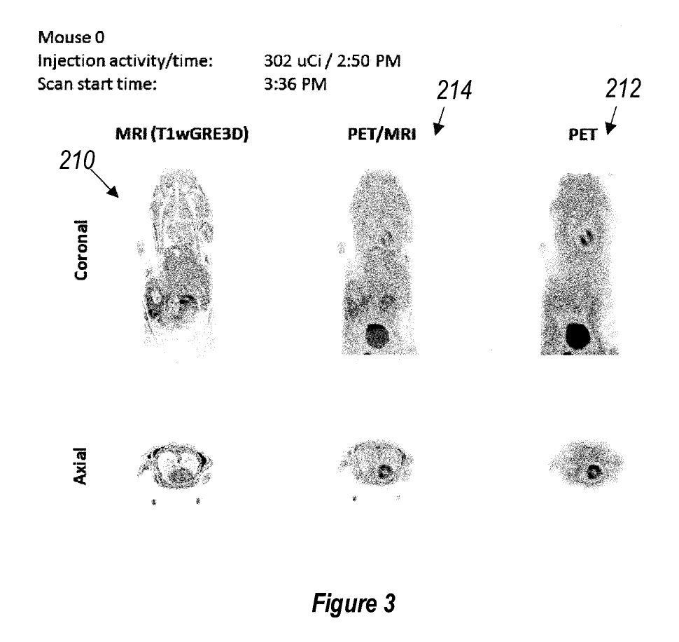

In various embodiments, the combining includes any one of registering, superimposing and/or fusing the MRI images and the PET images. In various embodiments, the combined images include spatially registered and/or temporally registered MRI images and PET images of subject 90 (or at least a portion of subject 90) acquired under identical physiological conditions. An example of combined PET-MRI image (e.g., generated by system 100) is described below with respect to FIG. 3.

Alternatively or complementarily, system 100 includes other detectors (not shown) that are not influenced by RF shielding generated by RF shield 130 (e.g., as described above). For example, system 100 can include optical detectors positioned external to RF coil bore 111 (not shown). In this case, RF shield 130 can include openings at predetermined locations along RF shield 130, to, for example, enable detection of photons emitted from subject 90 by the optical detectors thereof. Analysis unit 160 can be further arranged to generate at least one optical image (e.g., based on optical data received from the optical detectors) and further to combine the at least one optical image with the at least one MRI image and/or with the at least one PET image (e.g., as described above).

Reference is now made to FIG. 2A, which is a schematic illustration of a system for combined Positron-Emission Tomography (PET) and Magnetic Resonance Imaging (MRI), such as system 100, according to some embodiments of the invention.

System 100 can include a RF coil structure 160 and/or PET structure 170 (e.g., as shown in FIG. 2A). RF coil structure 160 and/or PET structure 170 can be used to, for example, insert RF coil 110 accommodating subject 90 and PET detectors array 120 into measurement volume 104 (e.g., within housing 106) of system 100 (e.g., as described below with respect to FIGS. 2B-2C).

Reference is now made to FIG. 2B, which shows schematic illustrations of a RF coil structure, such as RF coil structure 160, of a system for combined Positron-Emission Tomography (PET) and Magnetic Resonance Imaging (MRI), such as system 100, according to some embodiments of the invention.

Illustrations 160a and 160b in FIG. 2B show a RF coil structure 160 positioned external to housing 160 (e.g., in a non-operating position) and inside housing 106b (e.g., in an operating position), respectively. Illustration 160c in FIG. 2B shows a cradle 162 of RF coil structure 160 accommodating subject 90.

RF coil structure 160 can include, at RF coil structure's distal end 161a, a cradle 162. Cradle 162 can receive and accommodate a subject 90, for example a mouse.

In various embodiments, RF coil 110 is mounted on, or embedded within, a RF coil support 115 (e.g., as shown in FIG. 2B). RF coil support 115 can be mounted on cradle 162 such that RF coil 110 surrounds cradle 162. For example, RF coil support 110 can be thread onto cradle 162 such that RF coil bore 111 accommodates both subject 90 and cradle 162.

RF coil structure 160 can be inserted into housing 106b via, for example, an opening 106a on a front face 106b of housing 106. A RF coil structure's 160 length and/or cradle's 162 length can be determined to position cradle 162, RF coil 110 and subject 90 within predetermined measurement volume 104 within housing 106.

RF coil structure 160 can include a handle 164 affixed to a RF coil structure's proximal end 161b to, for example, insert and/or remove RF coil structure 160 into/from housing 106. RF coil structure 160 can be arranged to route RF coil's 110 wiring and/or medical tubing connected to subject 90 external to housing 106, e.g., through an interior 165 of RF coil structure 160 (e.g., as shown in FIG. 2G), while preventing (or substantially preventing) an external RF radiation from entering predetermined measurement volume 104 and/or preventing (or substantially preventing) RF radiation from exiting predetermined measurement volume 104.

Reference is now made to FIG. 2C, which shows schematic illustrations of a PET structure, such as PET structure 170, of a system for combined Positron-Emission Tomography (PET) and Magnetic Resonance Imaging (MRI), such as system 100, according to some embodiments of the invention.

Illustrations 170a and 170b in FIG. 2C show a PET structure 170 positioned partly external to housing 106b (e.g., in a non-operating position) and inside housing 106 (e.g., in an operating position), respectively. Illustration 170c in FIG. 2C shows PET detectors array 120 and PET structure 170 external to housing 106.

PET detectors array 120 can include one or more PET detectors array parts that can be mounted on a distal portion 171a of PET structure 170. For example, PET detectors array 120 can include a first PET detectors array part 120-1 and a second PET detectors array part 120-2 (e.g., as shown in FIG. 2C).

PET structure 170 can be inserted into housing 106b via, for example, an opening 106d on a back face 106c of housing 106. A PET structure's 170 length can be determined to position PET detectors array 120 mounted on PET structure's distal portion 171a within predetermined measurement volume 104 to thereby surround RF coil 110 and RF shield 130 (e.g., as described above with respect to FIG. 1).

PET structure 170 can be arranged to route PET detectors array's 120 wiring external to housing 106b (e.g., through an interior of PET structure 170) while preventing (or substantially preventing) an external RF radiation from entering predetermined measurement volume 104 and/or preventing (or substantially preventing) RF radiation from exiting predetermined measurement volume 104.

Reference is now made to FIG. 2D, which shows schematic illustrations of a radiofrequency (RF) shield, such as RF shield 130, of a system for combined Positron-Emission Tomography (PET) and Magnetic Resonance Imaging (MRI), such as system 100, including two RF shield parts 130-1, 130-2, according to some embodiments of the invention.

Illustration 130a in FIG. 2D shows a first RF shield part 130-1 and a second RF shield part 130-2. Illustration 130b in FIG. 2D shows a second RF shield part 130-2 external to housing 106. Illustration 130c in FIG. 2D shows first RF shield part 130-1 and second RF shield part 130-2 within housing 106.

In some embodiments, RF shield 130 includes two RF shield parts, for example, a first RF shield part 130-1 and a second RF shield part 130-2 (e.g., as shown in FIG. 2D). Each of first RF shield part 130-1 and second RF shield part 130-1 can include conductive material (e.g., copper). For example, each of first RF shield part 130-1 and/or second RF shield part 130-2 can be a copper cylinder and/or can be a substantially annular sleeve that can include a copper mesh.

In some embodiments, RF structure 160 is arranged to electrically connect, upon insertion into housing 106, to first RF shield part 130-1 and to second RF shield part 130-2 (e.g., as shown below in FIG. 2G) to form a Faraday cage to thereby provide RF shielding of system 100. The RF shielding can include, for example, preventing (or substantially preventing) RF radiation (e.g., generated by RF coil 110) from exiting predetermined measurement volume 104 and preventing (or substantially preventing) external RF radiation from entering predetermined measurement volume 104 and/or preventing (or substantially preventing) interference between RF coil 110 and PET detectors 120 (e.g., as described above with respect to FIG. 1).

Reference is now made to FIG. 2E, which is a schematic illustrations of a radiofrequency (RF) sleeve 135 of a system for combined Positron-Emission Tomography (PET) and Magnetic Resonance Imaging (MRI), such as system 100, according to some embodiments of the invention.

System 100 can include a RF sleeve 135. RF sleeve 135 can include a metal mesh 136b (e.g., made of conductive material, such as copper). Metal mesh 136b can be embedded within, for example, fabric material 137. In some embodiments, RF sleeve 135 envelopes cradle 162 of RF structure 160 accommodating RF coil 110 and subject 90. RF sleeve 135 can be electrically connected to RF structure 160 to form a Faraday cage to thereby provide additional RF shielding (e.g., additional to RF shielding provided by RF shield 130) of RF coil 110 and PET detectors 120 (e.g., as described above with respect to FIG. 1).

Reference is now made to FIG. 2F and FIG. 2G, which are schematic illustrations of a RF shield 130, RF coil structure 160 and PET structure 170 in a disassembled state external to housing 106b and in an assembled state within housing 106 of a system for combined Positron-Emission Tomography (PET) and Magnetic Resonance Imaging (MRI), such as system 100, respectively, according to some embodiments of the invention. Illustration 100c in FIG. 2F shows a perspective view and illustration 100d in FIG. 2G shows a cross-sectional view.

Positioning of RF coil structure 160 into operating position (e.g., as described above with respect to FIG. 2B) can locate cradle 162 and RF coil 110 (e.g., surrounding subject 90) within predetermined measurement volume 104. Positioning of PET structure 170 into operating position (e.g., as described above with respect to FIG. 2C) can locate PET detectors 120 to surround RF coil 110 and RF shield 130 (e.g., first RF shield part 130-1, as shown in FIG. 2G) along predetermined measurement volume 104.

Upon positioning of RF coil structure 160 and/or of PET structure 170 into the operative positions thereof, RF coil structure 160, PET structure 170, first RF shield part 130-land/or second RF shield part 130-2 can be electrically connected (e.g., as shown in FIG. 2G) to provide the Faraday cage (e.g., as described above with respect to FIG. 2D). The Faraday cage can provide RF shielding of system 100 to thereby prevent (or substantially prevent) RF radiation (e.g., generated by RF coil 110) from exiting predetermined measurement volume 104 and prevent external RF radiation from entering predetermined measurement volume 104 and/or prevent (or substantially prevent) interference between RF coil 110 and PET detectors 120 (e.g., as described above with respect to FIG. 1 and FIG. 2D).

In some embodiments, elements of system 100 (e.g., as described above with respect to FIG. 1 and FIGS. 2A-2G) are scaled in size for accommodation of an adult human, a portion of the adult human (e.g., a head), a human infant, a portion of the human infant (e.g., a head) and/or laboratory animals (e.g., rats, pigs, etc.).

Reference is now made to FIG. 3, which is an example of a simultaneously acquired MRI image 210 and PET image 212, and a combined PET-MRI image 214 of a subject 90, such as mouse, generated by a system for combined Positron-Emission Tomography (PET) and Magnetic Resonance Imaging (MRI), such as system 100, according to some embodiments of the invention.

Combining of simultaneously acquired MRI images 210 and PET images 212 into combined PET-MRI image 214 (e.g., as described above with respect to FIG. 1) allows to determine structural data (e.g., from MRI images) and functional (and/or molecular) data (e.g., from PET images 214) relating to subject 90, wherein the structural and the functional data is spatially and temporally registered and acquired under identical physiological conditions.

Some embodiments of the present invention can include a device for combined PET-MRI, which can be operative in a MRI device. For example, the MRI device (e.g., that can utilize superconductive magnets, permanent magnets and/or a combination thereof to generate a magnetic field) can be retrofitted to receive the device and to operate in combination with the device.

The device can include a RF coil having a RF coil bore that at least partly overlaps with a predetermined measurement volume of the MRI device and having a diameter to accommodate at least a portion of a subject (e.g., RF coil 110, as described above with respect to FIG. 1 and FIG. 2B). The RF coil can generate an electromagnetic field within the RF coil bore to excite nuclei within the at least portion of the subject and to receive signals emitted from the at least portion of the subject when the electromagnetic field is removed and the excited nuclei relax.

The device can include a PET detectors array surrounding the RF coil and to detect gamma rays emitted by positron-emitting (PE) radionuclides within the subject (e.g., PET detectors array 120, as described above with respect to FIG. 1 and FIG. 2C).

The device can include a RF shield surrounding the RF coil and positioned between the RF coil and the PET detectors array (e.g., RF shield 130, as described above with respect to FIG. 1, FIGS. 2D-2E and FIG. 2G).

In various embodiments, the device includes features from different embodiments of system 100 described above with respect to FIG. 1 and FIGS. 2A-2G. For example, the device can include a RF coil structure (e.g., RF coil structure 160, as described above with respect to FIG. 2B) and a PET structure (e.g., PET structure 170, as described above with respect to FIG. 2C) to thereby enable insertion of the device within the predetermined measurement volume of the MRI device; and/or the device can include an analysis unit (e.g., analysis unit 160, as described above with respect to FIG. 1), to generate combined PET MRI images (e.g., as described above with respect to FIG. 1 and FIG. 3).

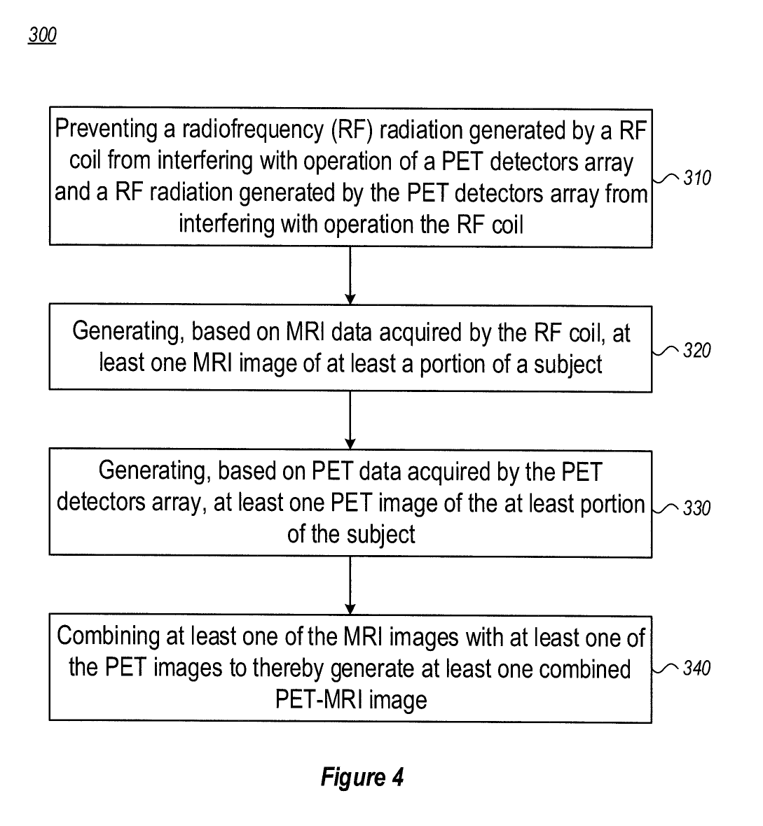

Reference is now made to FIG. 4, which is a flowchart of a method 300 of generating at least one combined magnetic resonance imaging (MRI) image and Positron-Emission Tomography (PET) image, according to some embodiments of the invention. Method 300 can be implemented by system 100, which may be configured to implement method 300.

Method 300 can include preventing 310 a radiofrequency (RF) radiation generated by a RF coil from interfering with operation of a PET detectors array and a RF radiation generated by the PET detectors array from interfering with operation the RF coil. For example, an RF shield can be positioned between the RF coil and the PET detectors array (e.g., as described above with respect to FIG. 1, FIGS. 2D-2E and FIG. 2G).

Method 300 can include generating 320 (e.g., by analysis unit 160, as described above with respect to FIG. 1), based on MRI data acquired by the RF coil, at least one MRI image (e.g., MRI image 210, as described above with respect to FIG. 3) of at least portion of a subject.

Method 300 can include generating 330 (e.g., by analysis unit 160, as described above with respect to FIG. 1), based on PET data acquired by the PET detectors array, at least one PET image (e.g., PET image 212, as described above with respect to FIG. 3) of the at least portion of the subject.

Method 300 can include combining 340 (e.g., by analysis unit 160, as described above with respect to FIG. 1) at least one of the MRI images with at least one of the PET images to thereby generate at least one combined PET-MRI image (e.g., combined PET-MRI image 214, as described above with respect to FIG. 3).

In various embodiments, method 300 includes operating the RF coil and the PET detectors array simultaneously (e.g., at the same time) or separately (e.g., at a predetermined time-delay with respect to each other) without any one of the RF coil, the PET detectors array or the subject being moved (e.g., as described above with respect to FIG. 1).

In various embodiments, the combining includes at least one of registering, superimposing, fusing or any combination thereof of at least one of the MRI images and at least one of the PET images. In various embodiments, the combined PET-MRI images include spatially registered and/or temporally registered MRI images and PET images of the subject (or at least a portion of the subject) acquired under identical physiological conditions (e.g., as described above with respect to FIG. 1).

One advantage of some embodiments of the present invention is that they allow simultaneous acquisition of MRI data of a subject, e.g., by a RF coil surrounding the subject, and PET data of the subject, e.g., by a PET detectors array surrounding the RF coil, without moving any one of the RF coils, the PET detectors array or the subject during an imaging procedure. Acquiring the MRI data and the PET data simultaneously (e.g., at the same time) can be achieved due to a RF shield surrounding the RF coil and positioned between the RF coil and the PET detectors array, which prevents an interference between the RF coil and the PET detectors array thereof. The simultaneous acquisition of the MRI data and the PET data allows determining a spatially and temporally registered structural, functional and/or molecular data acquired under identical physiological conditions.

In the above description, an embodiment is an example or implementation of the invention. The various appearances of “one embodiment”, “an embodiment”, “certain embodiments” or “some embodiments” do not necessarily all refer to the same embodiments. Although various features of the invention can be described in the context of a single embodiment, the features can also be provided separately or in any suitable combination. Conversely, although the invention can be described herein in the context of separate embodiments for clarity, the invention can also be implemented in a single embodiment. Certain embodiments of the invention can include features from different embodiments disclosed above, and certain embodiments can incorporate elements from other embodiments disclosed above. The disclosure of elements of the invention in the context of a specific embodiment is not to be taken as limiting their use in the specific embodiment alone. Furthermore, it is to be understood that the invention can be carried out or practiced in various ways and that the invention can be implemented in certain embodiments other than the ones outlined in the description above.

The invention is not limited to those diagrams or to the corresponding descriptions. For example, flow need not move through each illustrated box or state, or in exactly the same order as illustrated and described. Meanings of technical and scientific terms used herein are to be commonly understood as by one of ordinary skill in the art to which the invention belongs, unless otherwise defined. While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

1. A system for combined magnetic resonance imaging (MRI) and Positron-Emission Tomography (PET), the system comprising:
at least one magnet to generate a magnetic field within a predetermined measurement volume;
a radiofrequency (RF) coil having a RF coil bore that at least partly overlaps the predetermined measurement volume and having a diameter to accommodate at least a portion of a subject, the RF coil to generate an electromagnetic field within the RF coil bore to excite nuclei within the at least portion of the subject and to receive signals emitted from the at least portion of the subject when the electromagnetic field is removed and the excited nuclei relax;
a PET detectors array surrounding the RF coil and to detect gamma rays emitted by positron-emitting (PE) radionuclides within the subject; and
a RF shield surrounding the RF coil and positioned between the RF coil and the PET detectors array.

2. The system of claim 1, further comprising an analysis unit in communication with at least one of the RF coil and the PET detectors array, the analysis unit to:
generate, based on MRI data acquired by the RF coil, at least one MRI image of the at least portion of the subject;
generate, based on PET data acquired by the PET detectors array, at least one PET image of the at least portion of the subject; and
combine at least one of the MRI images with at least one of the PET images to thereby generate at least one combined PET-MRI image.

3. The system of claim 1, wherein the MRI device comprises at least one of permanent magnets, superconductive magnets or a combination thereof to generate a magnetic field within the predetermined measurement volume.

4. The system of claim 1, wherein the RF coil and the detector array are positioned such that the subject, RF coil and the detector array are stationary during operation.

5. The system of claim 1, wherein the RF shield comprises at least one of a cylinder or a mesh made from a conductive material.

6. The system of claim 1, wherein the RF shield to form a Faraday cage to thereby provide RF shielding of the system.

7. The system of claim 1, wherein the RF coil and the PET detectors array are positioned concentrically or at a predetermined radial distance with respect to each other.

8. The system of claim 2, wherein each of the at least one MRI image and the at least one PET image comprises at least one of a set of temporary sequential images, a set of spatial images or any combination thereof.

9. The system of claim 2, configured to perform the combining by at least one of registering, superimposing, fusing or any combination thereof of at least one of the MRI images and at least one of the PET images.

10. A method of generating at least one combined magnetic resonance imaging (MRI) image and Positron-Emission Tomography (PET) image, the method comprising:
preventing a radiofrequency (RF) radiation generated by a RF coil from interfering with operation of a PET detectors array and a RF radiation generated by the PET detectors array from interfering with operation the RF coil;
generating, based on MRI data acquired by the RF coil, at least one MRI image of at least a portion of a subject;
generating, based on PET data acquired by the PET detectors array, at least one PET image of the at least portion of the subject; and
combining at least one of the MRI images with at least one of the PET images to thereby generate at least one combined PET-MRI image.

11. The method of claim 10, further comprising operating the RF coil and the detector array simultaneously or separately without any one of the RF coil, the PET detectors array or the subject being moved during an imaging procedure.

12. The method of claim 10, wherein the combining comprises at least one of registering, superimposing, fusing or any combination thereof of at least one of the MRI images and at least one of the PET images.

13. A device for combined magnetic resonance imaging (MRI) and Positron-Emission Tomography (PET), which is operative in a MRI device, the device comprising:
a radiofrequency (RF) coil having a RF coil bore that at least partly overlaps a predetermined measurement volume of the MRI device and having a diameter to accommodate at least a portion of a subject, the RF coil to generate an electromagnetic field within the RF coil bore to excite nuclei within the at least portion of the subject and to receive signals emitted from the at least portion of the subject when the electromagnetic field is removed and the excited nuclei relax;
a PET detectors array surrounding the RF coil and to detect gamma rays emitted by positron-emitting (PE) radionuclides within the subject; and
a RF shield surrounding the RF coil and positioned between the RF coil and the PET detectors array.

14. The device of claim 13, further comprising an analysis unit in communication with at least one of the RF coil, the PET detectors array and the MRI device, the analysis unit to:
generate, based on MRI data acquired by the RF coil, at least one MRI image of the at least portion of the subject;
generate, based on PET data acquired by the PET detectors array, at least one PET image of the at least portion of the subject; and
combine at least one of the MRI images with at least one of the PET images to thereby generate at least one combined PET-MRI image.

15. The device of claim 13, wherein the MRI device comprises at least one of permanent magnets, superconductive magnets or a combination thereof to generate a magnetic field within the predetermined measurement volume of the MRI device.

16. The device of claim 13, wherein the RF coil and the detector array are positioned such that the subject, RF coil and the detector array are stationary during operation.

17. The device of claim 13, wherein the RF shield comprises at least one of a cylinder or a mesh made from a conductive material.

18. The device of claim 13, wherein the RF shield to form a Faraday cage to thereby provide RF shielding of the system.

19. The device of claim 14, wherein each of the at least one MRI image and the at least one PET image comprises at least one of a set of temporary sequential images, a set of spatial images or any combination thereof.

20. The device of claim 14, configured to perform the combining by at least one of registering, superimposing, fusing or any combination thereof of at least one of the MRI images and at least one of the PET images.
